(19) United States
(12) Patent Application Publication
(10) Pub. No.: US 2006/0175939 A1
(43) Pub. Date: Aug. 10, 2006

(54) Piezoelectric device and method of producing the same

(76) Inventor: Kazuo Murata, Nagano (JP)

Correspondence Address: Smith Gambrell & Russell, Suite 800, 1850 M Street NW, Washington, DC, 20036, US

(21) Appl. No.: 10/563,882

(22) PCT Filed: Jul. 9, 2004
(86) PCT No.: PCT/JP04/09810

§ 371 Date: Jan. 9, 2006

(30) Foreign Application Priority Data
Jul. 10, 2003 (JP) 2003-194684

(51) Int. Cl. H01L 41/08

(52) U.S. Cl. 310/368

(57) ABSTRACT

A piezoelectric element plate is rectangular as seen from above. Its upper surface is formed to be flat, while it lower surface has a beveling arc applied thereto. The piezoelectric plate is mounted on a package by adsorbing one longitudinal end of its upper surface (flat surface) by an adsorbing nozzle. Then, ultrasonic waves are applied through the adsorbing nozzle to a bump positioned between the package and one longitudinal end of the lower surface of the piezoelectric element plate, while pressing the piezoelectric element plate against the package by the adsorbing nozzle, whereby the piezoelectric element plate is joined to the package.

### TECHNICAL FIELD

The present invention relates to a piezoelectric device useful in ultrasonic joining and a method for manufacturing the piezoelectric device.

### BACKGROUND ART

Conventionally, in response to a demand for the miniaturization and thinning of electronic devices, density of electronic circuits has also been increased, and electronic components mounted on a circuit board are made into a small-sized chip similarly to other general electronic components, so as to become suitable for the thin-type high density mounting. As a result, many surface mounting devices (SMDs) which can be soldered only on one face of the circuit board have been commercialized. In recent years, there has been an increasing demand for further miniaturization, weight reduction and cost reduction of electronic components in accordance with spreading of the portable communication device and the like.

Because of the same circumstance as that described above, small SMD products have also been required for the piezoelectric device. However, in the conventional method for supporting a piezoelectric element plate by using solder and conductive adhesive, there is the possibility that when adhesion area is reduced to realize the miniaturization, the adhesive flows out to cause a short circuit. Also, there are problems that the position of the piezoelectric element plate tends to be unstable, and that a gas is generated from the adhesive to cause deterioration of electric characteristics of the piezoelectric element plate. Accordingly, a piezoelectric device having a structure in which a piezoelectric element plate is supported by utilizing a stud bump, is devised (for example, see Japanese Patent Application Laid-Open No. 8-298423). In this piezoelectric device, a gap between the piezoelectric element plate and a member to which the piezoelectric element plate is mounted, is formed by the stud bump. The distortion in the horizontal direction caused by a difference between thermal expansion coefficients of the piezoelectric element plate and the mounting member can be absorbed by the gap. Further, the gap has an effect of enabling the piezoelectric element plate to be joined to a package in a state where a horizontal posture of the piezoelectric element plate is maintained.

A thermo-compression bonding method and an ultrasonic welding method, using a bump, are already known (for example, see Japanese Patent Application Laid-Open No. 10-284972). The ultrasonic welding method is efficient because the heating temperature can be made lower than that in the thermo-compression bonding method, and the like.

In the case where the piezoelectric element plate is an AT plate, the AT plate having a flat plate shape is generally used in order to obtain high frequency vibration, so that the method described in the Japanese Patent Application Laid-Open No. 10-284972 can be used for joining the piezoelectric element plate. However, when the AT plate having flat plate shape is used to obtain relatively low frequency vibration, vibration energy loss is caused by the influence of the shape of the AT plate. Thus, bevel working and convex working are applied to the AT plate in order to reduce the vibration energy loss.

However, in the case where a longitudinal end part of the piezoelectric element plate subjected to the bevel working or the convex working is adsorbed by a nozzle, it is difficult to maintain the horizontal posture of the piezoelectric element plate. In this case, since the part of the piezoelectric element plate adsorbed by the nozzle is of an inclined surface, the tip of the nozzle and the piezoelectric element plate are not stably engaged with each other, so that when adsorbed by the nozzle, the piezoelectric element plate cannot be stably held in the horizontal state. As a result, when the piezoelectric element plate is adsorbed by the nozzle in mounting the piezoelectric element plate on a package, the piezoelectric element plate is inclined to contact the package or an electronic component such as an IC, thereby making it difficult to perform the mounting. This is because a mounting reference plane of a quartz piece adsorbed by the nozzle and the like becomes unstable at the time of mounting operation.

Further, even when the piezoelectric element plate is mounted on the package, the gap between the upper and lower sides of the piezoelectric element plate on the package needs to be set to be relatively large, which is disadvantageous for thinning the piezoelectric device.

Further, an exciting electrode part present in the vicinity of the center of the piezoelectric element plate has a flat plate shape or a shape near a flat plate, and it is possible to hold the piezoelectric element plate substantially in a horizontal state by adsorbing the vicinity of the center with the adsorbing nozzle, but in such adsorbing operation, there is the possibility that the exciting electrode mounted on the upper surface of the piezoelectric element plate is damaged.

### DISCLOSURE OF THE INVENTION

An object of the present invention is to provide a method for manufacturing a piezoelectric device in which a piezoelectric element plate is mounted and joined onto a package, the method enabling stable joint without damaging the exciting electrode which is important for the device characteristic, and also to provide the piezoelectric device.

In order to achieve the above described object, according to the present invention, there is provided a piezoelectric device comprising a piezoelectric element plate which is rectangular as seen from above, wherein one surface of the piezoelectric element plate is formed to be flat, and the other surface of the piezoelectric element plate is worked at both longitudinal end parts in a manner such that the thickness of the end parts gradually reduces toward both longitudinal end faces, and wherein the package and the piezoelectric element plate are joined with each other via a bump formed between the upper surface of the package and one longitudinal end part on the non-flat side surface of the piezoelectric element plate.

A first aspect of a method for manufacturing a piezoelectric device according to the present invention, comprising: forming a bump on a package; mounting a piezoelectric element plate which is rectangular as seen from above, the upper surface of which is formed to be flat, and the lower surface of which is worked at both longitudinal end parts in a manner such that the thickness of the end parts gradually reduces toward both longitudinal end faces, on the package to join the piezoelectric element plate to the package at one of the longitudinal end parts on the lower surface of the piezoelectric element plate via the bump with the upper surface of the piezoelectric element plate as reference; and joining the piezoelectric element plate to the package via the bump while pressing the piezoelectric element plate against the package.

The method for manufacturing the piezoelectric device, according to the first aspect of the present invention, further comprising: adsorbing one longitudinal end part of the piezoelectric element plate by an adsorbing nozzle to mount the piezoelectric element plate on the package with the flat upper surface of the piezoelectric element plate as reference; and joining the piezoelectric element plate to the package by applying ultrasonic waves while pressing the piezoelectric element plate against the package.

Further, a second aspect of a method for manufacturing a piezoelectric device according to the present invention, comprising: forming a bump at one longitudinal end part of the lower surface of the piezoelectric element plate which is rectangular as seen from above, the upper surface of which is formed to be flat, and the lower surface of which is worked at both longitudinal end parts in a manner such that the thickness of the end parts gradually reduces toward both longitudinal end faces; adsorbing one longitudinal end part of the upper surface of the piezoelectric element plate by an adsorbing nozzle; mounting the piezoelectric element plate adsorbed by the adsorbing nozzle on a package; and joining the piezoelectric element plate to the package by applying ultrasonic waves to the bump positioned between the package and the one longitudinal end part on the lower surface of the piezoelectric element plate via the adsorbing nozzle while pressing the piezoelectric element plate against the package via the adsorbing nozzle.

In the first and second aspects of the method for manufacturing the piezoelectric device according to the present invention, an extraction electrode extracted from an exciting electrode mounted on the upper surface of the piezoelectric element plate may be provided on one longitudinal end part on the upper surface of the piezoelectric element plate, and the adsorbing nozzle may have a recess formed at its tip part for adsorbing the piezoelectric element plate while avoiding contact with the extraction electrode.

In the piezoelectric device according to the present invention, it is possible to confine vibration energy in the piezoelectric element plate, with both longitudinal end parts of one surface of the piezoelectric element plate subjected to the bevel working or the convex working. Further, the other surface of the piezoelectric element plate is flattened, so as to make the piezoelectric element plate surely placed on a plane perpendicular to the axial center of the adsorbing nozzle when an optional portion of the flat surface is adsorbed by the adsorbing nozzle, as a result of which the piezoelectric element plate is mounted on the package with a fixed posture relative to the adsorbing nozzle kept at all times.

Thus, according to the present invention, when one longitudinal end part of the surface of the piezoelectric element plate is adsorbed by the adsorbing nozzle, the surface being subjected to the bevel working or the convex working, it is possible to eliminate the possibility that in accordance with a portion adsorbed by the nozzle, the posture of the piezoelectric element plate with respect to the adsorbing nozzle is variously changed because of a large fluctuation in the bevel shape and the convex shape due to the working, and that the exciting electrode present at the central part of the piezoelectric element plate is damaged by adsorbing the central part of piezoelectric element plate with the adsorbing nozzle in order to stabilize the posture of the piezoelectric element plate with respect to the adsorbing nozzle.

Further, according to the present invention, the part of the piezoelectric element plate adsorbed by the adsorbing nozzle can be positioned so as to correspond to the position of a bump formed in advance between the package and the piezoelectric element plate, so that it is possible to adsorb the piezoelectric element plate by the adsorbing nozzle in a fixed posture, to press the piezoelectric element plate against the bump, and further to apply ultrasonic waves to the bump.

### BRIEF DESCRIPTION OF THE DRAWINGS

FIG. 1 is a top view showing an embodiment of a quartz oscillator according to the present invention;

FIG. 2 is a sectional view taken along line X-X in FIG. 1;

FIG. 3 is a top view, a bottom view, and a side view for explaining a shape of the quartz oscillator shown in FIG. 2;

FIG. 4A is a sectional view showing a state before a quartz piece is mounted on a package;

FIG. 4B is a sectional view showing a state after the quartz piece is mounted on the package;

FIG. 5 is a sectional view taken along line Y-Y in FIG. 4B; and

FIG. 6 is a sectional view showing a modification of the adsorbing nozzle shown in FIG. 5.

### BEST MODE FOR CARRYING OUT THE INVENTION

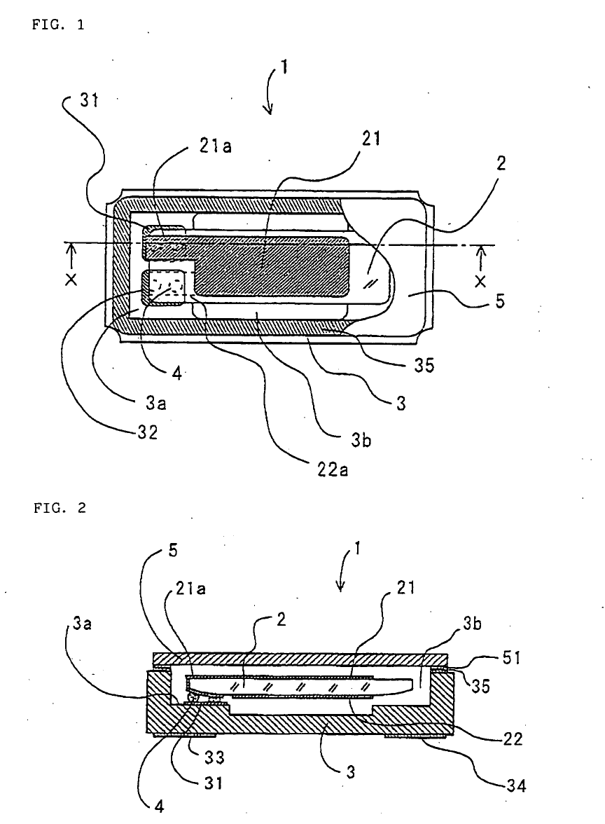

First, a configuration of a quartz oscillator as an embodiment of a piezoelectric device according to the present invention is described with reference to FIG. 1 to FIG. 3. The quartz oscillator 1 comprises a quartz piece 2 which is rectangular as seen from above and which is a piezoelectric element plate, a package 3 made of ceramics and a lid member 5 for sealing the package.

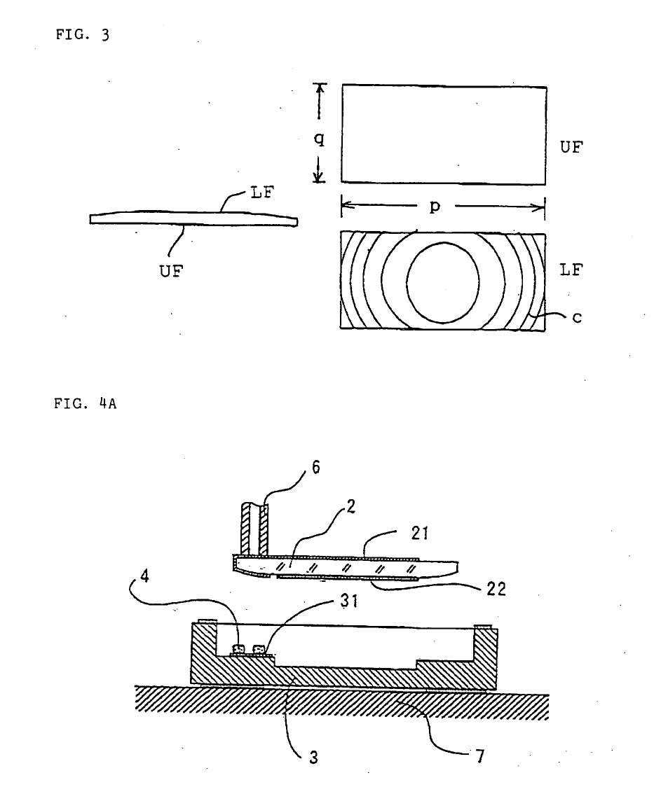

The quartz piece 2 is rectangular as seen from above, the longer side (dimension p) of which is set to the oscillating displacement direction, and the shorter side (dimension q) of which is set to the direction perpendicular to the long side, as shown in FIG. 3. One surface UF (hereinafter referred to as the upper surface) of the quartz piece 2 is a flat surface, and the other surface LF (hereinafter referred to as the lower surface) is formed into a beveling circular arc form having both longitudinal end parts the thickness of which is made to be gradually reduced toward the tip of the both longitudinal end parts. A plurality of circular arcs c represent the contour lines.

An exciting electrode 21 is mounted on the upper surface of the quartz piece 2, and an exciting electrode 22 is mounted on the lower surface of the quartz piece 2. Further, an extraction electrode 22a extracted from the lower exciting electrode 22 (FIG. 5) is extended on one longitudinal end part (part formed with the beveling circular arc) on the lower surface of the quartz piece 2. On the other hand, an extraction electrode 21a extracted from the upper exciting electrode 21 is extended to one longitudinal end part on the upper surface of the quartz piece 2, and further extended to go around the end face of the quartz piece 2 and then to reach the part formed with the beveling circular arc. As a result, as shown in FIG. 5, extraction electrodes 21a, 22a extracted from the exciting electrodes 21, 22 are disposed on the left and right in parallel on the part formed with the beveling circular arc on the lower surface of the quartz piece 2.

The package 3 comprises, as shown in FIG. 2, a cavity 3b in which a stage part 3a for mounting the quartz piece 2 is formed. At parts of the stage part 3a which correspond to the extraction electrodes 21a, 22a of the quartz piece 2 mounted on the stage part 3a, connection electrodes 31, 32 are formed of a metalized layer, respectively.

At the both longitudinal end parts on the bottom surface of the package 3, a pair of terminal electrodes 33, 34 for external connection are formed of the metalized layer. The connection electrodes 31, 32 and the terminal electrodes 33, 34 are electrically connected with each other by electric wirings (not shown) in the package 3, respectively. Further, on the upper end face of the package 3, a frame-like lid member joint part 35 is formed of the metalized layer so as to surround the cavity 3b.

A gold plating is applied to each of the metalized layers of which the connection electrodes 31, 32, the terminal electrodes 33, 34 and the lid member joint part 35 are formed.

In FIG. 2, reference numeral 4 denotes a plurality of stud bumps formed of a wire mainly composed of Au, and are press contacted by solid phase diffusion to the surface of the extraction electrodes 21a, 22a or the surface of the connection electrodes 31, 32 in advance, by application of ultrasonic waves.

Then, as shown in FIG. 5, the extraction electrodes 21a, 22a are joined with the connection electrodes 31, 32 via the stud bumps 4, 4, respectively.

The lid member 5 has a flat shape, and a blazing filler layer 51 made of a metallic material having a low melting temperature such as an Au/Sn alloy is formed at a part of the lid member 5 corresponding to the lid member joint part 35 formed on the upper end face of the package 3. As a result, the airtightness of the cavity 3b in the package 3 is maintained by joining the blazing filler layer 51 of the lid member 5 to the lid member joint part 35 of the package 3. As a joining method of the lid member 5, various methods such as a seam welding method and a laser welding method, may be adopted other than the brazing method, and that as a junction material, various materials such as a low melting point glass can also be used other than the Au/Su alloy.

As described above, in this application, with the plate shape side of the upper surface of the piezoelectric device as the mounting reference, the surface of the piezoelectric device, along which the thickness of the piezoelectric device is gradually reduced toward the both longitudinal end faces of the piezoelectric device, is joined to the package via the bumps, so that it is possible to perform mounting in a state where the upper surface is in parallel with the package, and to thereby obtain an extremely thin piezoelectric device. In addition, since both end parts of the piezoelectric device have a bevel shape, it is possible to obtain stable vibration.

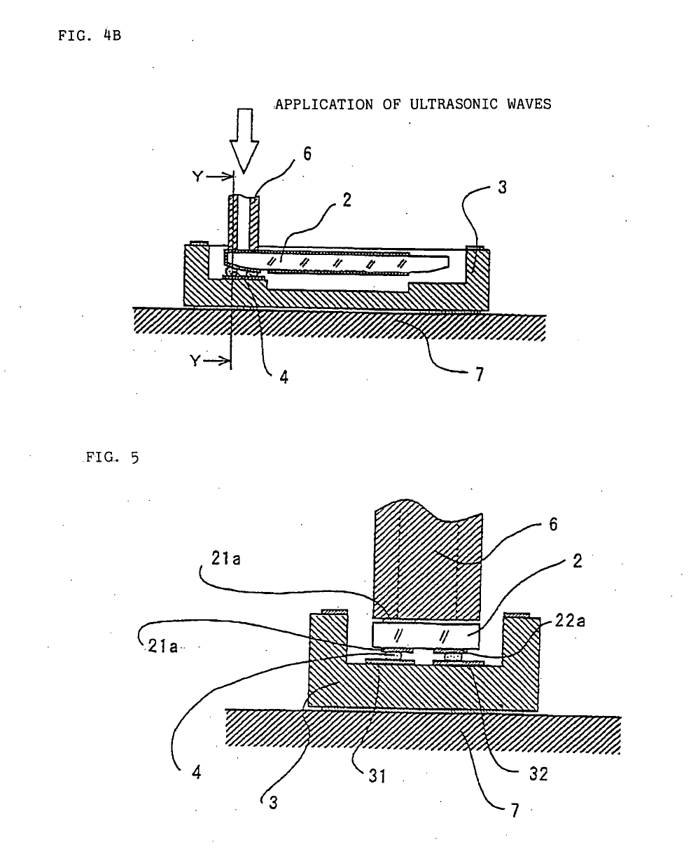

Next, a method for manufacturing the quartz oscillator shown in FIG. 1 and FIG. 2 is described with reference to FIG. 4A, FIG. 4B and FIG. 5. Here, among methods for manufacturing the quartz oscillator, there is described a method for mounting the quartz piece 2 on the package 3, which method is a feature of the present invention.

In FIG. 4A and FIG. 4B, reference numeral 6 denotes a tip part of a vacuum adsorbing nozzle capable of applying ultrasonic waves, and reference numeral 7 denotes a hot plate.

First, in order to preheat the package 3, the package 3 is mounted on the hot plate 7. Then, the stud bumps 4 are formed by an Au wire on the connection electrodes 31, 32 of the package 3. The stud bumps may be formed in advance in another step.

Next, an end part of the side of the extraction electrode 21a on the upper surface (surface of the flat side) of the quartz piece 2 is adsorbed and held by the adsorbing nozzle 6, so that the quartz piece 2 is held just above the package 3, as shown in FIG. 4A. Whether the surface of the quartz piece 2 is the surface (surface of the flat side) to be adsorbed by the adsorbing nozzle 6 or the opposite surface is determined for example by judging whether circular contour lines appear or not when an image of the surface of the quartz piece 2 is taken by a camera and processed. Alternatively, the surface to be adsorbed can also be determined on the basis of a feature of shapes obtained by imaging the exciting electrodes 21, 22 and the extraction electrodes 21a, 22a by using a camera.

Next, as shown by the arrow in FIG. 4B, the quartz piece 2 is lowered toward the package 3, while being held by the adsorbing nozzle 6, so that the stud bumps 4 formed on the connection electrodes 31, 32 of the package 3 are thermo-compression bonded at a predetermined pressure with the pair of extraction electrodes 21a, 22a formed on the part provided with the beveling circular arc on the lower surface of the quartz piece 2. Further, ultrasonic waves are applied from the adsorbing nozzle 6 simultaneously with the thermo-compression bonding operation.

As described above, the part adsorbed by the adsorbing nozzle 6 on the upper surface (surface of the flat side) of the quartz piece 2 is the end part of the side on which the extraction electrode 21a is present. Thus, as shown in FIG. 5, when the adsorbing surface of the adsorbing nozzle 6 is flat, apart of the adsorbing surface abuts the extraction electrode 21a, but the remaining part of the adsorbing surface faces the upper surface of the quartz piece 2 with a space. However, since the thickness of the extraction electrode 21a is about 1000 Å, the space does not hinder the adsorbing operation by means of the nozzle 6.

In this way, in the present embodiment, it is possible to obtain an effect to confine vibration energy in the quartz piece 2 by making one surface of the quartz piece 2 into a beveling circular arc form (or convex form), and the other surface is made to be flat so as to enable the posture of the quartz piece 2 always to be fixed with respect to the adsorbing nozzle 6 when an optional part on the flattened surface, specifically one longitudinal end side corresponding to the bumps is adsorbed by the adsorbing nozzle 6.

Therefore, in the present embodiment, when an end part of the flat side surface of the quartz piece 2 (part corresponding to the position where the stud bumps are formed) is adsorbed by the adsorbing nozzle 6 in order to mount the quartz piece 2 on the package 3, the quartz piece 2 adsorbed by the adsorbing nozzle 6 is positioned on the surface perpendicular to the axial center of the adsorbing nozzle 6, that is, disposed in a posture in parallel with the bottom surface of the package 3.

On the other hand, when the end part of the quartz piece formed into the beveling circular arc form or the convex form is adsorbed by the adsorbing nozzle as in the conventional case, the posture (degree of inclination) of the quartz piece with respect to the adsorbing nozzle is changed in accordance with the part adsorbed by the adsorbing nozzle, as a result of which a part of the quartz piece may collide with the package 3 in mounting the quartz piece on the package. Alternatively, when the central flat part of the quartz piece is adsorbed by the adsorbing nozzle in order to avoid the above described situation, the exciting electrode which is normally provided in the central part of the quartz piece may be damaged.

However, according to the present invention, since one surface of the quartz piece is made flat as described above, even when an end part of the flat surface is adsorbed by the adsorbing nozzle so as to avoid the part in which the exciting electrode is present, it is possible to maintain the horizontal posture of the quartz piece and to eliminate the risk of damaging the exciting electrode by the adsorbing operation using the adsorbing nozzle. Further, as the flat surface of the quartz piece is disposed in parallel with the lower surface of the package, miniaturization can be achieved as much as possible.

As described above, according to the present embodiment, it is possible to efficiently and stably perform an operation for mounting the quartz piece on the package by adsorbing the end part of the quartz piece with the adsorbing nozzle, and thereafter to apply ultrasonic waves to the stud bumps from the adsorbing nozzle positioned at the end part of the quartz piece.

An oscillator can be formed by combining the quartz piece and an IC. However, the connection electrodes 31, 32 and the terminal electrodes 33, 34 for external connection of the package 3 are not connected in this case.

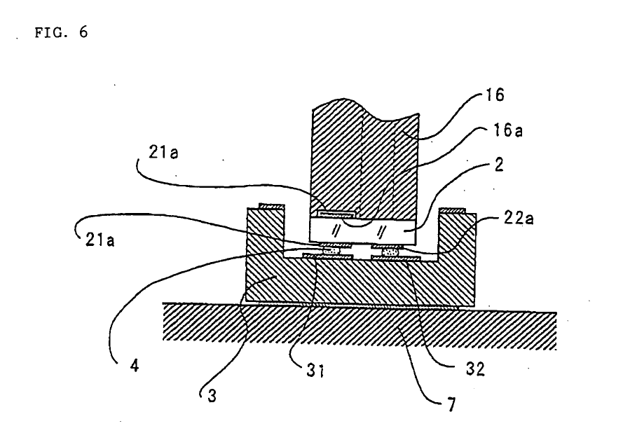

Next, a modification of the adsorbing nozzle for adsorbing the quartz piece 2 is described with reference to FIG. 6.

In the case of quartz, damage to the exciting electrode needs to be surely avoided, but slight damage to the extraction electrode may be permitted. However, even for the extraction electrode, it is necessary to prevent the damage and to improve electric conduction. To this end, as shown in FIG. 6, a recess 16a as a relief part for preventing contact with the extraction electrode 21a extracted from the upper exciting electrode is formed on the adsorbing surface of the adsorbing nozzle 16. As a result, when adsorbing the quartz piece, the adsorbing nozzle 16 abuts at its tip surface the surface of the quartz piece but does not abut the extraction electrode 21a, so that the adsorbing nozzle 16 is capable of holding the quartz piece 2 without damaging extraction electrode 21a.

In the present embodiment, there is described a case where a plurality of stud bumps 4 are formed in advance on the surface of the connection electrodes 31, 32, that is, on the side of the package 3, but instead, the plurality of stud bumps 4 may be formed in advance on the surface of the extraction electrodes 21a, 22a, that is, on the side of the quartz piece 2. Further, the number of stud bumps to be formed may be one or more. For example, two stud bumps are arranged on one of the connection electrode 31 and two stud bumps are arranged on the connection electrode 32 so that each of the two stud bumps are arranged at an interval in the longitudinal direction of the quartz piece 2.

As described above, in the embodiments according to the present invention, there is described the AT plate of the quartz oscillator which is a piezoelectric device, but the present invention can be applied to piezoelectric devices such as other resonators and oscillators. Further, the beveling form of the quartz piece 2 is not limited to the circular arc form, but an inclined surface shape may also be used as the beveling form of the quartz piece 2. As described above, as an oscillator is constituted by combining a quartz piece and an IC, the details of which are based on known techniques, and hence will not be further described.

1. A piezoelectric device constituted by mounting and joining a piezoelectric element plate to a package,
wherein the piezoelectric element plate is rectangular as seen from above, one surface of the piezoelectric element plate is formed to be flat, and the other surface of the piezoelectric element plate is worked at both longitudinal end parts in a manner such that the thickness of the end parts gradually reduces toward both longitudinal end faces, and
wherein the package and the piezoelectric element plate are joined with each other via a bump formed between the upper surface of the package and one longitudinal end part on said other surface of the piezoelectric element plate.

2. The piezoelectric device according to claim 1, wherein beveling circular arc form is formed at both end parts on the non-flat side surface of the piezoelectric element plate.

3. A method for manufacturing a piezoelectric device, comprising:
forming a bump on a package;
mounting a piezoelectric element plate which is rectangular as seen from above, the upper surface of which is formed to be flat, and the lower surface of which is worked at both longitudinal end parts in a manner such that the thickness of the end parts gradually reduces toward both longitudinal end faces, on the package to join the piezoelectric element plate to the package at one of the longitudinal end parts on the lower surface of the piezoelectric element plate via the bump with the upper surface of the piezoelectric element plate as reference; and
joining the piezoelectric element plate to the package via the bump while pressing the piezoelectric element plate against the package.

4. The method for manufacturing the piezoelectric device according to claim 3, further comprising:
adsorbing one of the longitudinal end parts of the piezoelectric element plate by an adsorbing nozzle to mount the piezoelectric element plate on the package with the flat upper surface of the piezoelectric element plate as reference; and
joining the piezoelectric element plate to the package by applying ultrasonic waves while pressing the piezoelectric element plate against the package.

5. A method for manufacturing a piezoelectric device, comprising:
forming a bump at one longitudinal end part of the lower surface of the piezoelectric element plate which is rectangular as seen from above, the upper surface of which is formed to be flat, and the lower surface of which is worked at both longitudinal end parts in a manner such that the thickness of the end parts gradually reduces toward both longitudinal end faces;
adsorbing one of the longitudinal end parts of the upper surface of the piezoelectric element plate by an adsorbing nozzle;
mounting the piezoelectric element plate adsorbed by the adsorbing nozzle on a package; and
joining the piezoelectric element plate to the package by applying ultrasonic waves to the bump positioned between the package and the one of the longitudinal end parts on the lower surface of the piezoelectric element plate via the adsorbing nozzle while pressing the piezoelectric element plate against the package by means of the adsorbing nozzle.

6. The method for manufacturing the piezoelectric device according to claim 4 or 5, wherein an extraction electrode extracted from an exciting electrode mounted on the upper surface of the piezoelectric element plate is provided on said one of the longitudinal end parts on the upper surface of the piezoelectric element plate, and wherein the adsorbing nozzle has a recess formed at the tip part of the nozzle for adsorbing the piezoelectric element plate while preventing contact with the extraction electrode.

7. The method for manufacturing a piezoelectric device according to any one of claims 3, 4 and 5, wherein a beveling circular arc form is formed at both end parts on the surface of the non-flat side of the piezoelectric element plate.
